(19) United States
(12) Patent Application Publication
(10) Pub. No.: US 2022/0392848 A1
(43) Pub. Date: Dec. 8, 2022

(54) INTEGRATED CIRCUIT WITH PROGRAMMABLE RADIATION TOLERANCE

(71) Applicant: BAE SYSTEMS Information and Electronic Systems Integration Inc., Nashua, NH (US)

(72) Inventors: Jason F. Ross, Haymarket, VA (US); Dale A. Rickard, Manassas, VA (US)

(73) Assignee: BAE SYSTEMS Information and Electronic Systems Integration Inc., Nashua, NH (US)

(21) Appl. No.: 17/340,807

(22) Filed: Jun. 7, 2021

(51) Int. Cl. H01L 23/552; G06F 30/398

(52) U.S. Cl. CPC H01L 23/552; G06F 30/398

(57) ABSTRACT

An integrated circuit (IC) that is otherwise radiation tolerant implements a radiation tolerance limiting feature (RTLF) to ensure that the IC, as manufactured, will fail applicable radiation tolerance tests, thereby allowing it to be manufactured by any suitable IC foundry. Embodiments further include a programmable radiation tolerance feature (PRT) that can be actuated at an authorized actuation site after IC manufacture to override the RTLF, thereby rendering the IC radiation tolerant. The PRT and/or RTLF can include redundancy to ensure reliability. The PRT and/or RTLF can be obfuscated, encrypted, and/or password protected. Actuating the PRT can include applying a programming signal to the IC and/or uploading code to a programmable element after IC manufacture. A plurality of RTLFs can be included to ensure failure of any desired combination of applicable radiation tolerance tests, such as total radiation dosage, linear energy transfer events, radiation dose rate, and single event upset.

### FIELD

The present disclosure relates to integrated circuits, and more particularly to integrated circuits that are configured to reliably fail applicable radiation tolerance tests.

### BACKGROUND

Most integrated circuits (ICs) are intended for terrestrial use in environments that are not subject to radiation exposure beyond what is normal at the earth's surface. There are, however, some applications in which ICs must be “radiation hardened” so that they will function reliably in a high radiation environment, such as in space, or proximal to nuclear reactors. There are several strategies that can be employed to radiation harden an IC design. These include adjusting dimensions and other features of the IC design to minimize radiation effects, providing radiation shielding, and/or including fault-tolerance features in the IC such as redundancy and/or error correction.

Radiation hardened ICs are often useful for supporting government regulated activities, including incorporation of the ICs into certain military and surveillance systems. As such, foundries that produce radiation hardened ICs, referred to herein as “radiation certified” foundries, are subject to special governmental controls, scrutiny, and other requirements, including extensive reporting and documentation requirements, as well as secrecy requirements. Radiation hardened ICs are also frequently subject to export restrictions.

So as to distinguish between ICs that are deemed to be “radiation hardened” and those that are not, governments typically issue regulations that specify a set of radiation tolerance tests and corresponding tolerance thresholds, wherein separate radiation tolerance tests and thresholds are used to measure the sensitivity of an IC to each of several different characteristics of radiation exposure. For example, separate tests and tolerance thresholds may be defined for total radiation dosage, neutron flux, single event charged particle impacts, dose rate, and single event upsets. In each case, an IC will be deemed to pass a radiation tolerance test if it does not fail when exposed to an amount of radiation that meets or exceeds the associated tolerance threshold. The regulations further divide ICs into categories according to their functions and other factors, and specify which of the tests are applicable to each category of IC. Accordingly, in general, special restrictions and requirements as specified in the regulations will apply to an IC that falls in a given category if and only if it passes one or more of the radiation tolerance tests that are “applicable” to that type of IC.

Radiation tolerance tests and tolerance thresholds that are applicable to integrated circuits manufactured in the United States are specified in the International Traffic in Arms Regulations (ITAR) and the Export Administration Regulations (EAR). Examples of such tests include total ionizing dose (TID)≥500 Krds, prompt dose≥5×10⁸ rads(Si)/sec, neutron dose≥1×10¹⁴ n/cm², and/or Single Event Upset (SEU)≤1×10⁴⁰ errors/bit-day (Heavy Ion).

For IC manufacturers that do not wish to be radiation certified, because they wish to avoid the special requirements and restrictions that apply to radiation certified foundries, it can therefore be important that all of the ICs that they manufacture will reliably fail all of their applicable radiation tolerance tests.

As used herein, an IC's “applicable radiation tolerance tests” refers to the radiation tolerance tests that are defined in one or more government regulations, such as ITAR and EAR, and are specified in the regulations to apply to the category to which the IC belongs. ICs that reliably fail all of their applicable radiation tolerance tests are referred to herein as “radiation intolerant” ICs, while ICs that reliably pass at least one of their applicable radiation tolerance tests are referred to herein as “radiation tolerant” ICs. Radiation tolerant ICs that meet more stringent, application specific radiation tolerance requirements, in addition to passing their applicable radiation tolerance tests, are referred to herein as “radiation hardened” ICs.

Generally, radiation hardened ICs are required to meet a set of stringent, “real world” requirements based on engineering considerations, so that the IC will be suitable for implementation in a specified high radiation environment, such as in space. As such, radiation hardened ICs will also be radiation “tolerant,” in that they can be expected to pass most or all of the less stringent, applicable radiation tolerance tests that are specified in government regulations such as EAR and ITAR.

On the other hand, ICs that are not intended to be used in high radiation environments can fail the applicable radiation tolerance tests by a considerable margin, and still be suitable for exposure to the very low radiation levels that are present at the earth's surface.

Of course, IC designs that are intended to fail their applicable radiation tolerance tests will generally not include any special radiation tolerant features, such as shielding or wide critical node spacing. Nevertheless, some of the recent advances in semiconductor processes that have been adopted to improve the performance of microprocessors and other ICs have also tended to increase the radiation tolerance of some types of ICs. For example, modern ICs that operate at lower voltages, and that implement smaller transistors with thinner oxide layers, tend to be much less susceptible to radiation than their counterparts produced just a few years ago. Thus, there is a possibility that some modern IC designs, while intended only for terrestrial, civilian use, may nevertheless inadvertently and unintentionally pass one or more of their applicable radiation tolerance tests.

Accordingly, there is a strong concern among foundries that are not radiation certified that accidental production of ICs that unintentionally pass at least one of their applicable radiation tolerance tests could be deemed to be radiation tolerant, and could thereby subject the foundry to the heightened scrutiny and other requirements that apply to radiation certified foundries. One approach to avoiding this possibility is to test each IC design for radiation tolerance. However, testing an IC to verify that it fails all of its applicable radiation tolerance tests can be expensive and time consuming, and can require specialized testing apparatus. As a result, many IC foundries that are not radiation certified cannot afford to test each new IC design for radiation tolerance. At the same time, it is necessary for many foundries that are not radiation certified to implement the latest improvements in IC design and manufacture, so as to remain competitive in the marketplace.

One approach to avoiding inadvertent production of ICs that may pass an applicable total radiation dosage test is to implement a feature within an integrated circuit design that is specifically intended to disable or cripple the IC, or certain features of the IC, upon exposure to a specified total radiation dosage, thereby causing the IC to reliably fail the applicable total radiation dosage test, while allowing the IC to function normally so long as the total radiation dosage remains below a defined radiation threshold. Typically, such radiation dosage limiting features include components and circuitry that are configured to detect and/or measure a total radiation dosage, and to issue an IC-disabling signal once a specified total radiation dosage has been received, thereby ensuring that the IC will reliably fail the applicable total radiation dosage tolerance test, even if the IC design would otherwise pass the test.

However, this approach only ensures that the IC will fail total radiation dosage tolerance tests, and does not ensure that the IC will fail any of its other applicable radiation tolerance tests, and thereby does not fully address the concerns of chip foundries that wish to avoid falling under the special requirements and restrictions that apply to radiation certified foundries by producing only radiation intolerant ICs.

Because radiation hardened ICs must be produced by radiation certified foundries, their production costs are increased, due both to the added regulatory expenses that are incurred by radiation certified foundries, and due to the relatively low quantities of radiation hardened ICs that are typically produced at one time. Furthermore, radiation certified foundries often lag technologically behind the most advanced IC foundries, thereby limiting the design choices and performance of radiation hardened ICs.

What is needed, therefore, is an IC design approach which ensures that ICs intended for civilian, terrestrial use will reliably fail any desired combination of radiation tolerance tests, while preferably also reducing the cost of producing functionally similar or identical radiation hardened ICs that are intended for domestic use in high radiation environments.

### SUMMARY

The present disclosure is a method of designing ICs which ensures that all of the ICs, as of the time of their manufacture, will reliably fail any desired combination of radiation tolerance tests that are imposed by applicable radiation tolerance standards such as EAR and ITAR. Embodiments also reduce the cost of producing functionally similar or identical radiation hardened ICs that are intended for domestic use in high radiation environments.

According to the present disclosure, an IC design includes a “functional section” that is radiation hardened, but also includes at least one radiation tolerance limiting feature (RTLF) that is configured to ensure that the IC, as initially manufactured, will reliably fail at least one of its applicable radiation tolerance tests, and preferably all of its applicable radiation tolerance tests. In various embodiments, the RTLF is “triggered” when exposed to a specified type and amount of radiation, referred to herein as a “trigger threshold,” after which it functions to disable the IC, for example by reducing or shorting a required voltage, issuing a reset signal to the functional section, and/or disabling a signal that is required by the functional section, such as a clock signal. By including a plurality of RTLFs, the IC can be designed to fail any desired combination of corresponding radiation tolerance tests.

Embodiments further include one or more “programmable radiation tolerance” (PRT) features that can be actuated at an approved and certified programming center, after initial production of the IC, to disable or bypass the one or more RTLFs, thereby converting the radiation intolerant IC into a radiation tolerant IC. ICs that incorporate one or more RTLF in combination with one or more corresponding PRTs are referred to herein as PRT ICs. ICs that incorporate one or more of the disclosed RTLFs, but do not incorporate any PRT features, are referred to herein as permanently radiation intolerant ICs, or xRAD ICs.

The present disclosure thereby enables foundries that are not “radiation certified,” including the most advanced foundries, to produce the disclosed xRAD ICs and/or PRT ICs in large quantities as radiation intolerant ICs that will reliably fail their applicable radiation tolerance tests, and will therefore be suitable for general use and export. Once a quantity of PRT ICs has been manufactured, some or all of the PRT ICs can then be transferred to a secure, approved and certified programming center that is authorized to produce radiation tolerant ICs, where the PRT features of the ICs can be actuated. This step is referred to herein as “programming” the PRT IC. The resulting radiation tolerant ICs thereby benefit from being manufactured at the most suitable foundry, as well as from the much lower production costs of an IC foundry that is not radiation certified, while incurring only a minor added cost associated with the much simpler, post-manufacturing step of PRT actuation. Embodiments realize a further cost benefit due to economy of scale by producing large quantities of PRT ICs, even if only a subset will subsequently be programmed to be radiation hardened.

Costs of producing the disclosed xRAD and PRT ICs can be even further reduced by developing a library of RTLFs and combined RTLF/PRT “IP cores” that are initially incorporated into test ICs and subjected to thorough radiation exposure testing. If the trigger threshold of an RTLF can be adjusted by changing the values of one or more adjustment components, for example by varying the value of one or more resistors in a voltage divider circuit, the optimal values of the adjustment components can also be determined during this testing phase. For example, the trigger threshold can be adjusted so that it is approximately one half of the tolerance threshold that is specified in an applicable radiation tolerance test. In embodiments, the adjustment components are implemented in the test ICs as variable components, such as variable resistors and capacitors, so that optimal values can be easily determined. Subsequently, fixed components can be substituted for these variable components in the IP core library. After the IP cores have been tested and optimized, they can then typically be incorporated into any new IC design in any desired combination, without requiring additional testing. Based on previous IP core testing conditions and results, an analysis of the new IC design can be applied in each case to indicate whether the selected IP cores can be implemented with confidence, or whether further testing may be needed.

According to the present disclosure, the RTLF and/or PRT features that are included in a PRT IC can be protected from unauthorized actuation by any of several approaches, used either alone or in combination. One such approach is to obfuscate the PRT within the IC design, so that it becomes very difficult to recognize and/or analyze the RTLF and/or PRT based on examination of the lithography mask designs of the IC or analysis of the IC die. As an example, the RTLF and/or PRT can be designed to mimic a different type of circuit, such as an Electrostatic Discharge (ESD) protection circuit, that is commonly included in ICs. Another example is to widely separate different portions of the RTLF and/or PRT at different locations within the IC, so that it becomes very difficult to recognize that the separated portions function together as a RTLF or PRT.

Another approach for preventing unauthorized PRT actuation is to implement one or more of the PRTs in a programmable element, such as a field programmable gate array (FPGA), that is included in the IC design. As originally manufactured, the programmable element can be unprogrammed, or perhaps programmed to perform some other, innocuous task. Subsequent actuation of the PRT then includes reprogramming the programmable element so that it will function to bypass or disable the RTLF.

Still another approach is to include a password recognition circuit in the PRT, such that actuation of the PRT requires input of a password, thereby preventing unauthorized actuation of the PRT. To provide additional protection against unauthorized PRT actuation, the password and/or programming code can be protected from reverse engineering by including cryptographic hashing as part of the decoding function of the IC.

Embodiments implement still other forms of secure integrated circuit design and processing that can incorporate a variety of protection schemes to prevent unauthorized intrusion or modification of the integrated circuit's intended function.

The scope of the present disclosure includes a wide variety of RTLF and PRT approaches. Some exemplary and enabling examples of RTLF and PRT approaches are presented herein. However, the recited RTLF and PRT examples do not limit the scope of the disclosure. Additional variations would readily occur to one of skill in the art in light of the examples presented herein.

In some embodiments of the present disclosure, an RTLF includes a MOSFET, oxide dielectric capacitor, or other “leakage” component or circuit that will be damaged and will develop a leakage current if a voltage is applied across the leakage component while the leakage component or circuit is exposed to radiation. The radiation-induced leakage can be configured to reduce or short a required voltage within the PRT IC or xRAD IC, and/or to short an input to a gate or change the input to a voltage comparator within the IC, for example by forming part of a voltage divider configured such that a change in leakage will cause the voltage divider to change its output state, which serves as an input to a voltage comparator, thereby blocking a required signal within the IC or causing the voltage comparator to issue a disabling logic signal that resets or otherwise disables the IC.

In other embodiments, an RTLF includes a photocurrent generating component that produces a photocurrent in response to a radiation dose rate event. The photocurrent generating component can be implemented as part of a voltage divider that provides an input to a voltage comparator, as described in the previous example.

In yet other embodiments, an RTLF includes at least one “single event upset” (SEU) capture element that is susceptible to radiation-induced SEUs. The SEU capture element is initially forced to a logic zero state by a power-on reset circuit, but transitions to a logic one state when an SEU occurs due to radiation exposure. The output of the SEU capture element can be directed to a comparator or logic gate, to the gate input of a MOSFET that is configured to short a required voltage, and/or to an input of a gate that is configured to block a required signal of the IC.

In various embodiments, a PRT can block, bypass, or otherwise inactivate an RTLF in any of several ways. For example, if the RTLF includes a leakage component, and if the sensitivity of the leakage component to damage by radiation is proportional to a voltage that is applied across the leakage component, the PRT can function to remove the voltage that is applied across the leakage component, thereby virtually eliminating its sensitivity to radiation damage.

In some embodiments where an RTLF includes an SEU capture element, comparator, or other circuit or gate that issues a disabling logic signal when the RTLF is exposed to radiation, the corresponding PRT includes a signal-blocking circuit, such as an OR gate or NAND gate, that is configured to block or ignore the logic signal issued by the RTLF when the PRT is actuated.

In embodiments, the RTLF and/or the PRT include redundancies in their design that minimize any possibility that an RTLF could fail to disable the IC upon exposure to radiation, or that a PRT, when actuated, could fail to disable the corresponding RTLF.

A first general aspect of the present disclosure is an integrated circuit (IC) having programmable radiation tolerance. The IC includes a functionality section that is configured to withstand exposure to radiation up to a specified functional threshold, thereby ensuring that the functionality section is suitable for implementation in a high radiation environment, a radiation tolerance limiting feature (RTLF) that is configured, when it is triggered, to partially or fully disable operation of the functionality section, the RTLF being triggered when it is exposed to radiation above a specified RTLF trigger threshold, the RTLF trigger threshold being low enough to ensure that the IC will fail at least one applicable radiation tolerance test as specified by an applicable regulatory requirement, a programming input, and a programmable radiation tolerance (PRT) feature that can be actuated after initial manufacture of the IC via the programming input so as to override the RTLF and thereby maintain or restore operation of the functionality section despite triggering of the RTLF, thereby rendering the IC suitable for implementation in the high radiation environment.

In embodiments, at least one of the RTLF and PRT is obfuscated within the IC design, thereby hindering recognition, and reverse engineering of the RTLF and/or PRT based on examination of lithography mask designs of the IC or analysis of the IC die. In some of these embodiments, at least one of the RTLF and PRT is configured to appear similar to another common IC circuit that does not function as a RTLF or PRT. In any of these embodiments, at least one of the RTLF and PRT ca be distributed among a plurality of physical locations within the IC.

In any of the above embodiments, the PRT can be configured to be actuated by uploading instructions via the programming input into a programmable element that is included within the PRT. In some of these embodiments, the programmable element is a field programmable gate array (FPGA). In any of these embodiments, the uploaded instructions can be encrypted.

In any of the above embodiments, the PRT can include a password recognition feature that enables actuation of the PRT only when a specified password is entered via the programming input. In some of these embodiments the decoding function of the IC includes cryptographic hashing, thereby preventing discovery of the password by reverse engineering of the IC.

In any of the above embodiments, the RTLF can be configured to cause a required voltage of the IC to be reduced when the RTLF is triggered.

In any of the above embodiments, the RTLF can be configured to issue a disabling signal that disables the functional section when the RTLF is triggered.

In any of the above embodiments, the RTLF can include a leakage component or circuit that is configured to develop a leakage when the leakage component or circuit is exposed to radiation while a voltage is applied to the leakage component or circuit. In some of these embodiments, the leakage component or circuit comprises at least one of an oxide dielectric capacitor, a radiation-sensitive MOSFET, a radiation-sensitive silicon-controlled rectifier (SCR), and a photocurrent generating component or circuit. In any of these embodiments, the leakage component can be implemented as part of a voltage divider that directs a leakage voltage to an input of a voltage comparator, and wherein the voltage comparator is configured to compare the leakage voltage with a reference voltage, and to cause the RTLF to be triggered when the leakage voltage transitions from being greater than the reference voltage to being less than the reference voltage, or vice versa.

In any of the above embodiments, the IC can include a plurality of RTLFs, thereby ensuring that the IC will fail a corresponding plurality of applicable radiation tolerance tests.

In any of the above embodiments, the PRT can be configured, when actuated, to prevent a disabling signal issued by the RTLF from acting upon the functional section.

In any of the above embodiments, the PRT can be configured, when actuated, to prevent application of a voltage to a leakage component or circuit of the RTLF.

In any of the above embodiments, the IC can include a redundancy feature comprising a plurality of RTLFs directed to ensuring that the IC will fail the applicable radiation tolerance test, and the IC will fail the specified radiation tolerance test, so long as any one of the RTLFs remains functional and the PRT has not been actuated.

In any of the above embodiments, the IC can include a redundancy feature comprising a plurality of PRTs, whereby the RTLF will remain overridden so long as any one of the PRTs remains functional and is actuated.

In any of the above embodiments, upon initial manufacture, the RTLF can cause the IC to comply with radiation related export restrictions under at least one of the United States International Traffic in Arms Regulations (ITAR) and the United States Export Administration Regulations (EAR) by being outside of requirements of those regulations, such that export restrictions specified by those regulations do not apply to the IC, and actuating the PRT after initial manufacture of the IC can cause the IC to become subject to the export restrictions under at least one of the United States International Traffic in Arms Regulations (ITAR) and the United States Export Administration Regulations (EAR).

In any of the above embodiments, the RTLF trigger threshold can be adjustable by changing a value of at least one adjustment component of the RTLF.

In any of the above embodiments, the RTLF trigger threshold can be adjustable by changing a value of a voltage applied across a radiation sensitive component of the RTLF.

In any of the above embodiments, the IC can include a RTLF testing output that can be monitored without permanently triggering the RTLF to determine whether the RTLF is able to disable the functional section of the IC when it is triggered and the PRT is not actuated.

In any of the above embodiments, the IC can include a PRT testing output that can be monitored without permanently actuating the PRT to determine whether the PRT is able to override the RTLF.

A second general aspect of the present disclosure is a method of manufacturing a radiation tolerant IC. The method includes manufacturing of an IC according to the first general aspect by an IC foundry that is not authorized to manufacture ICs that will pass an applicable radiation tolerance test as specified in an applicable regulatory requirement, transferring of the IC from the IC foundry to an actuation center that is authorized to produce ICs that will pass the applicable radiation tolerance test, and actuating of the PRT of the IC by the actuation center.

In some of these embodiments the method further includes manufacturing of a plurality of the ICs by the IC foundry, distributing a first subset of the plurality of ICs to the actuation center, actuating by the actuation center of the first subset of ICs, and after actuating the first subset of ICs, distributing the first subset of ICs from the actuation center for implementation in a high radiation environment. And some of these embodiments further include distributing a second subset of the plurality of ICs from the IC foundry for implementation in a low radiation environment, wherein none of the plurality of ICs is included in both the first subset and the second subset.

The features and advantages described herein are not all-inclusive and, in particular, many additional features and advantages will be apparent to one of ordinary skill in the art in view of the drawings, specification, and claims. Moreover, it should be noted that the language used in the specification has been principally selected for readability and instructional purposes, and not to limit the scope of the inventive subject matter.

### BRIEF DESCRIPTION OF THE DRAWINGS

FIG. 1A is a block diagram that illustrates the fundamental elements included in PRT IC embodiments of the present disclosure;

FIG. 1B is a block diagram that illustrates the fundamental elements included in an xRAD IC embodiments of the present disclosure;

FIG. 2A is an illustration that is suggestive of the concept of obfuscation of a RTLF or PRT by causing the RTLF or PRT to resemble another type of circuit according to an embodiment of the present disclosure;

FIG. 2B illustrates obfuscation of a RTLF or PRT by distributing elements of the RTLF or PRT at different locations and/or layers of an xRAD IC or PRT IC, according to an embodiment of the present disclosure;

FIG. 3A illustrates actuation of a PRT by adding or changing the operating code of a programmable element within the PRT IC subsequent to the manufacture thereof, according to an embodiment of the present disclosure;

FIG. 3B illustrates actuation of a PRT by inputting a password into the PRT IC subsequent to the manufacture thereof, according to an embodiment of the present disclosure;

FIG. 4A is a circuit diagram that illustrates a PRT and RTLF circuit that implements a radiation sensitive leakage capacitor as part of a single event gate rupture RTLF, according to an exemplary embodiment of the present disclosure;

FIG. 4B is a circuit diagram that illustrates a PRT and RTLF circuit similar to FIG. 4A that illustrates the application of redundancy to the RTLF/PRT circuit of FIG. 4A, according to an exemplary embodiment of the present disclosure;

FIG. 4C is a flow diagram that illustrates verification of the functionality of a plurality of PRTs in an embodiment of the present disclosure;

FIG. 4D is a circuit diagram that illustrates a PRT and RTLF circuit similar to FIG. 4A, in which the leakage capacitor is replaced by a radiation sensitive MOSFET, and the RTLF is a total ionizing dose RTLF, according to an exemplary embodiment of the present disclosure;

FIG. 4E is a circuit diagram that illustrates a PRT and RTLF circuit similar to FIG. 4A, in which the leakage capacitor is replaced by a photocurrent generating component, and the RTLF is a dose rate RTLF, according to an exemplary embodiment of the present disclosure;

FIG. 4F is a circuit diagram that illustrates a PRT and RTLF circuit similar to FIG. 4A, in which the leakage capacitor is replaced by a radiation sensitive leakage circuit, and the RTLF is a single event latchup RTLF, according to an exemplary embodiment of the present disclosure;

FIG. 5A is a circuit diagram that illustrates a PRT and RTLF circuit that implements a leakage component as part of a voltage divider that supplies an input to a voltage comparator, wherein the RTLF is a single event gate rupture RTLF, according to an exemplary embodiment of the present disclosure where the leakage component is a leakage capacitor;

FIG. 5B is a circuit diagram that illustrates a PRT and RTLF circuit that implements a leakage component as part of a voltage divider that supplies an input to a voltage comparator, wherein the RTLF is a dose rate RTLF, according to an exemplary embodiment of the present disclosure where the leakage component is a photocurrent generating component;

FIG. 5C is a circuit diagram that illustrates a PRT and RTLF circuit that implements a leakage component as part of a voltage divider that supplies an input to a voltage comparator, wherein the RTLF is a total ionizing dose RTLF, according to an exemplary embodiment of the present disclosure where the leakage component is a radiation sensitive leakage circuit;

FIG. 6 is a circuit diagram that illustrates a PRT and RTLF circuit that is similar to FIG. 5C, except that the leakage component is a leakage circuit, and that the embodiment further comprises an additional MOSFET that eliminates the voltage applied across the leakage circuit when the PRT is actuated, wherein the RTLF is a single event latchup RTLF, according to an exemplary embodiment of the present disclosure;

FIG. 7 is a circuit diagram that illustrates a PRT and RTLF circuit wherein the RTLF includes an SEU capture element, according to an exemplary embodiment of the present disclosure;

FIG. 8A is a circuit diagram that includes the RTLF but not the PRT of FIG. 4B, according to an xRAD IC embodiment of the present disclosure;

FIG. 8B is a circuit diagram that includes the RTLF but not the PRT of FIG. 4D, according to an xRAD IC embodiment of the present disclosure;

FIG. 8C is a circuit diagram that includes the RTLF but not the PRT of FIG. 4E, according to an xRAD IC embodiment of the present disclosure;

FIG. 8D is a circuit diagram that includes the RTLF but not the PRT of FIG. 4F, according to an xRAD IC embodiment of the present disclosure;

FIG. 9A is a circuit diagram that includes the RTLF but not the PRT of FIG. 5A, according to an xRAD IC embodiment of the present disclosure;

FIG. 9B is a circuit diagram that includes the RTLF but not the PRT of FIG. 5B, according to an xRAD IC embodiment of the present disclosure;

FIG. 9C is a circuit diagram that includes the RTLF but not the PRT part of FIG. 5C;

FIG. 10 is a circuit diagram that includes the RTLF but not the PRT of FIG. 6, according to an xRAD IC embodiment of the present disclosure;

FIG. 11A is a circuit diagram that includes the RTLF but not the PRT of FIG. 7, according to an xRAD IC embodiment of the present disclosure;

FIG. 11B is a circuit diagram similar to FIG. 11A, but simpler in design; and

FIG. 12 is a flow diagram that illustrates a method of manufacturing a radiation tolerant IC according to an embodiment of the present disclosure.

### DETAILED DESCRIPTION

The present disclosure is a method of designing ICs which ensures that all of the ICs, as of the time of manufacture, will reliably fail any desired combination of radiation tolerance tests that are imposed by applicable radiation tolerance regulations such as EAR and ITAR. Embodiments also reduce the cost of producing functionally similar or identical radiation hardened ICs that are intended for domestic use in high radiation environments.

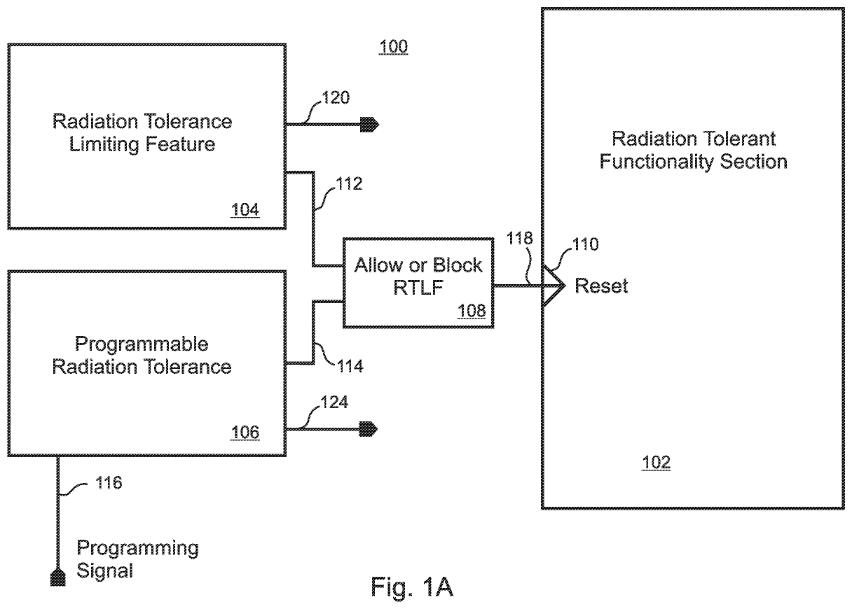

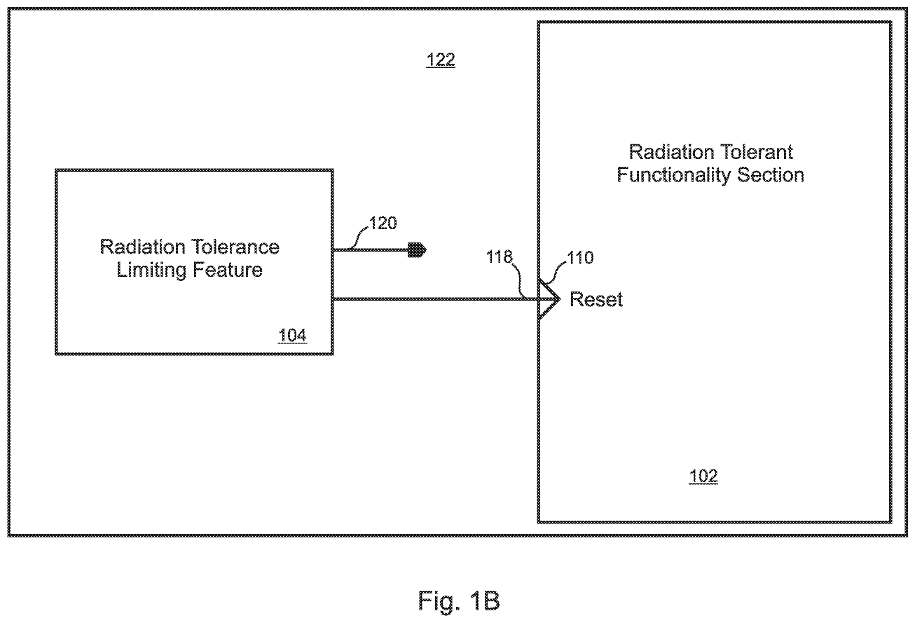

With reference to FIG. 1A, according to the present disclosure, a “programmable radiation tolerance” IC, referred to herein as a “PRT IC” 100 includes a functionality section 102 that is radiation tolerant, but otherwise functions in a manner that is similar or identical to a radiation intolerant IC. The PRT IC 100 further includes at least one radiation tolerance limiting feature (RTLF) 104 that is configured to ensure that the PRT IC 100, as initially manufactured, will reliably fail at least one applicable radiation tolerance test. Embodiments include a plurality of RTLFs 104 so as to ensure that the IC will fail any desired group of applicable radiation tolerance tests, and in some of these embodiments the IC includes sufficient RTLFs 104 to ensure that it will fail all of its applicable radiation tolerance tests. It can thereby be ensured that production of the IC will not cause the manufacturing foundry to be subject to any of the special certifications, reporting, security, and scrutiny that apply to radiation certified foundries.

In the simplified example of FIG. 1A, the ability of the RTLF 104, when exposed to radiation, to disable the functionality section 102 is indicated as a control signal 112 issued by the RTLF 104 that generates a disabling signal 118 directed to a “reset” input 110 of the functionality section 102. In other embodiments, the RTLF 104 is configured to reduce or eliminate a voltage that is required by the functionality section 102. In still other embodiments, the RTLF 104 is configured to block a signal, such as a clock signal, that is required by the functional section 102.

Also included in the disclosed PRT IC 100 is at least one “programmable radiation tolerance” (PRT) feature 106 that initially allows the RTLF to disable the functional section 102, but can be actuated at a secure, certified facility after initial production of the PRT IC 100 to disable or bypass the RTLF 104, thereby causing the PRT IC to become radiation tolerant. This actuation of the PRT 106 is referred to herein as “programming” the PRT IC, and the input 116 that is used to actuate the PRT 106 is referred to as the “programming” input 116. The ability of the PRT 106 to allow or block the action of the RTLF 104 can be implemented in many different ways, and is indicated in FIG. 1A simply as a functional box 108 that allows or blocks the ability of the RTLF to disable the functional section 102 according to a programming input 114 supplied by the PRT 106.

Embodiments further include an alarm signal 124 indicating that the PRT 106 has been actuated, and/or a test signal output 120 that can be monitored to verify that the RTLF 104 has been triggered.

It will be understood that FIG. 1A is intended only to indicate the basic functionalities of the disclosed PRT IC 100, and is not intended to imply any specific implementation or circuit. It will also be understood that any combination of one or more RTLFs 104 and PRTs 106 can be included in an embodiment, that a given RTLF 104 can, in general, ensure that the IC will fail more than one applicable radiation tolerance test, and that a given PRT 106 can, in general, deactivate more than one RTLF 104. It will be further understood that any reference herein to an RTLF 104 or a PRT 106 in the singular should be interpreted to also refer to embodiments that include a plurality of RTLFs and/or PRTs, unless otherwise required by context.

After the initial manufacture of a batch of PRT ICs 100, some or all of them can then be transferred to a secure facility that is authorized and certified to produce radiation tolerant ICs, where the PRTs 106 can be actuated via their programming input(s) 116, thereby converting the PRT ICs 100 into radiation tolerant ICs. The resulting radiation tolerant ICs 100 thereby benefit from being manufactured at the most suitable foundry, as well as from the much lower production costs of an IC foundry that is not radiation certified, while incurring only a minor added cost associated with the much simpler, post-manufacturing step of PRT actuation. Embodiments realize a further cost benefit due to economy of scale, by producing large quantities of PRT ICs, even if only a subset will subsequently be programmed to be radiation tolerant.

In the simple example of FIG. 1A, the action of the PRT 106 upon the RTLF 104 to allow, or when actuated, to disable or block the functionality of the RTLF 104 is implemented as a logic signal 114 that is directed by the PRT 106 to a logic AND gate 108. In this simplified example, upon initial manufacture, the logic signal 114 of the PRT 106 will be set to logic 1 thereby allowing the AND gate 108 to output the value of the disabling signal 112 of the RTLF 104. Additionally, upon initial manufacture, the disabling signal 112 of the RTLF 104 will be set to logic 0, thereby causing the output 118 of the AND gate 108 to be logic 0, which will allow the functional section 102 to operate normally. But when the RTLF 104 is triggered due to radiation exposure, it will transition the disabling signal 112 to logic 1, causing the output 118 of the AND gate 108 to be logic 1, and thereby activating the reset 110 and disabling the functional section 102.

However, when the PRT 106 is actuated via the programming input 116, so that the logic signal 114 is logic 0, the AND gate 108 will apply a logic 0 to the reset 110 regardless of the status of the RTLF 104 and the disabling signal 112, thereby enabling the PRT IC 100 to function as a radiation tolerant IC. In embodiments, actuation of the PRT 106 is accomplished by applying a suitable voltage across specified pins of the PRT IC 100, in a manner similar to programming a “programmable read only memory” (PROM).

With reference to FIG. 1B, the RTLFs 104 that are disclosed herein can also be included in an IC without also including a corresponding PRT 106. The resulting ICs 122 are permanently radiation intolerant, and are referred to herein as xRAD ICs 122. The RTLF 104 in the xRAD 122 of FIG. 1B functions in the same manner as the RTLF in FIG. 1A. However, the PRT 106 of FIG. 1A is omitted from the xRAD of FIG. 1B.

It is notable that the RTLFs 104 that are disclosed herein are not limited to only ensuring that the IC will fail total radiation dosage tolerance tests. Instead, ICs are disclosed herein that incorporate RTLFs 104 that will ensure that the IC will fail any desired combination of one or more of its applicable radiation tolerance tests.

Due to the incorporation of the RTLF 104, the disclosed PRT IC 100 or xRAD IC 122 can therefore be produced in large quantities by IC foundries that are not radiation certified, and will be suitable for general use and export, because the PRT ICs 100 or xRAD ICs 122, as initially manufactured, will fail their applicable radiation tolerance tests, and will be deemed to be radiation intolerant ICs.

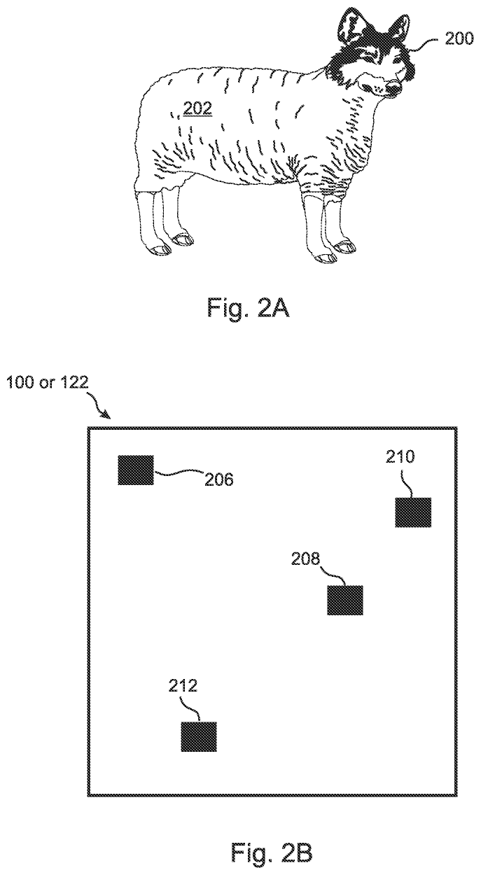

According to the present disclosure, any combination of the RTLF 104 and/or PRT 106 features that are included in a PRT IC 100 or xRAD IC 122 can be protected from unauthorized actuation or reverse engineering by any of several approaches, used either alone or in combination. With reference to FIG. 2A, one such approach is to obfuscate the RTLF 104 and/or PRT 106 within the IC design, so that it becomes very difficult to recognize and/or analyze or reverse engineer the RTLF 104 and/or PRT 106 based on examination of lithography mask designs of the PRT IC 100 or analysis of the PRT IC die. As an example, the RTLF 104 or PRT 106 can be designed to mimic a different type of circuit, such as an Electrostatic Discharge (ESD) protection circuit, that is commonly included in ICs. This approach is symbolically indicated in FIG. 2A as a “wolf” 200 that is mostly covered and obscured by the fleece of a sheep 202, where the “wolf” represents a RTLF 104 or PRT 106 that is “hidden” or obfuscated by appearing to be a different type of circuit (a “sheep”).

With reference to FIG. 2B, another approach to protecting an RTLF 104 or PRT 106 from detection is to widely separate different portions 206, 208, 210, 212 of the RTLF 104 or PRT 106 at different locations within the PRT IC 100 or xRAD IC 122, so that it becomes very difficult to recognize that the separated portions 206, 208, 210, 212 function together as a RTLF 104 or PRT 106. In the simplified illustration of FIG. 2B, the RTLF 104 or PRT 106 is divided into four portions 206, 208, 210, 212 that are distributed at different locations on the IC.

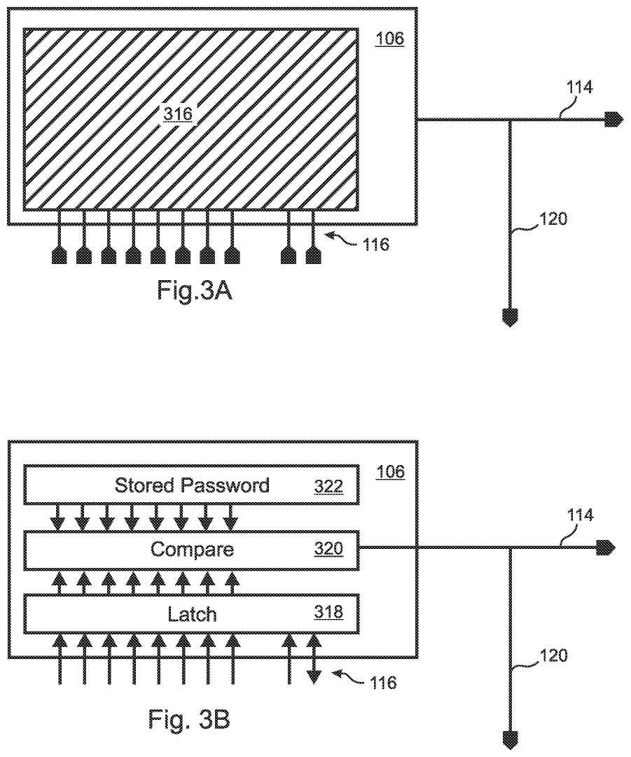

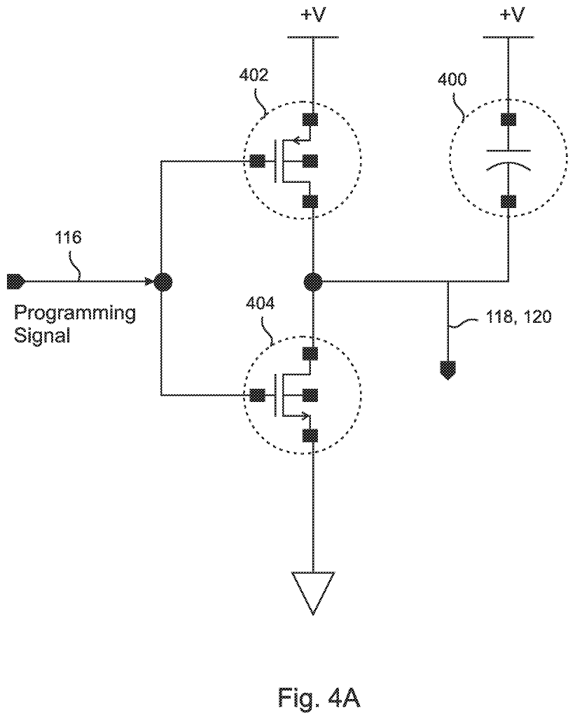

With reference to FIG. 3A, an approach for preventing unauthorized PRT actuation is to implement some or all of the PRT 106 and/or the PRT programming controls in a programmable element 316 such as a field programmable gate array (FPGA) 316 included in the IC design. As originally manufactured, the FPGA 316 is unprogrammed, or possibly programmed to perform some other, innocuous task. Subsequent actuation of the PRT 106 then includes reprogramming the FPGA 316 so that the PRT 106 will function to bypass or disable the RTLF 104.

With reference to FIG. 3B, still another approach to protecting a PRT 106 from unauthorized actuation is to include a password recognition circuit 318, 320, 322 in the PRT 106, such that activation of the PRT 106 requires input of a password as a programming input 116, thereby preventing unauthorized actuation of the PRT 106. In the simplified illustration of FIG. 3B, a password is applied to the programming input 116 and held in a latch 318. The correct password has been previously stored in a PROM 322. A comparator 320 accepts input from both the latch 318 and the PROM 322, and if the two match the comparator 320 causes the PRT 106 to deactivate or bypass the RTLF 104.

In embodiments, the uploaded programming code of the programmable element 316 of FIG. 3A and/or the stored password 322 of FIG. 3B can be encrypted or “hashed” so as to prevent discovery of the programming code or password by reverse engineering.

There are a number of other secure designing and processing technologies that incorporate anti-tamper protection schemes on integrated circuits to prevent unauthorized tampering or access that are implemented in embodiments of the present application, as will be known to one of skill in the art.

The scope of the present disclosure includes a wide variety of RTLF 104 and PRT 106 approaches. Some examples of RTLF 104 and PRT 106 approaches are presented in the drawings and described herein that are exemplary and enabling. Included among the illustrated examples are RTLF 104 approaches that will render the IC, as manufactured by the foundry, intolerant to at least one of total radiation dosage, events over a Linear Energy Transfer (LET) level (e.g. via gate rupture), Single Event Latchup (SEL), radiation dose rate, and Single Event Upset (SEU), However, the RTLF 104 and PRT 106 examples recited herein do not limit the scope of the disclosure. It should also be noted that the terms “RTLF” and “PRT” refer to functionalities of the PRT IC 100 or xRAD IC 122. In various embodiments, the RTLF 104 and PRT 106 of a PRT IC 100 are partially or entirely blended into a single element, circuit, or “IP core.”

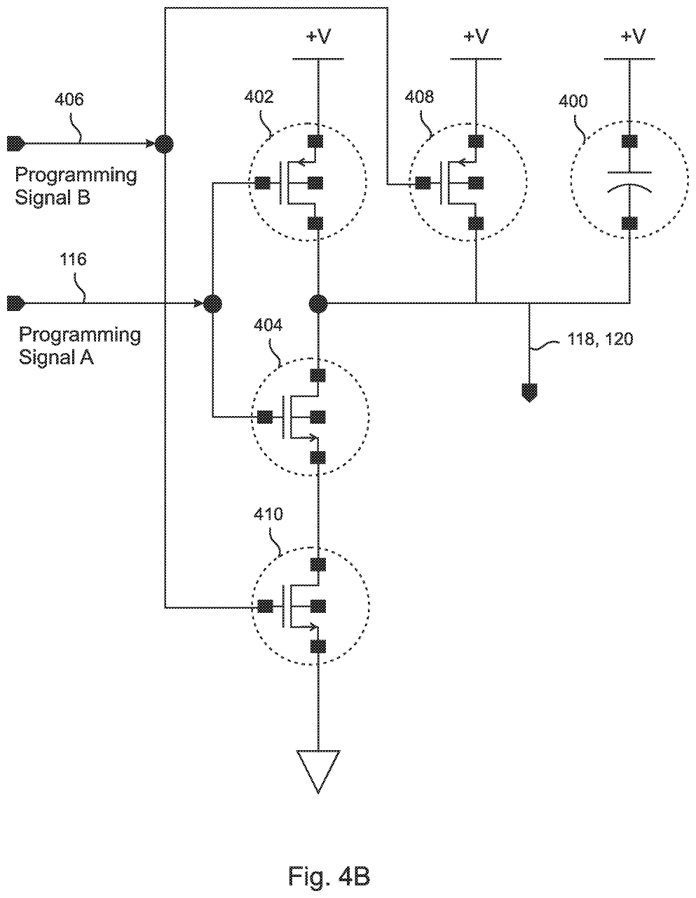

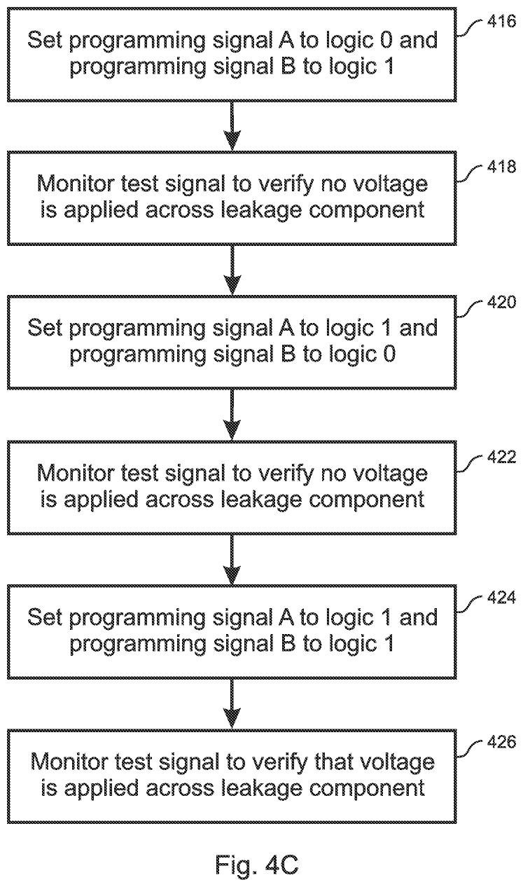

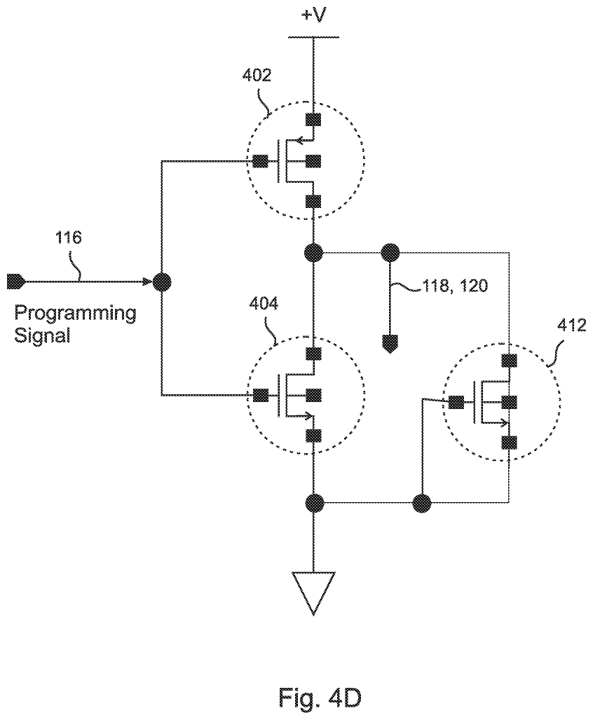

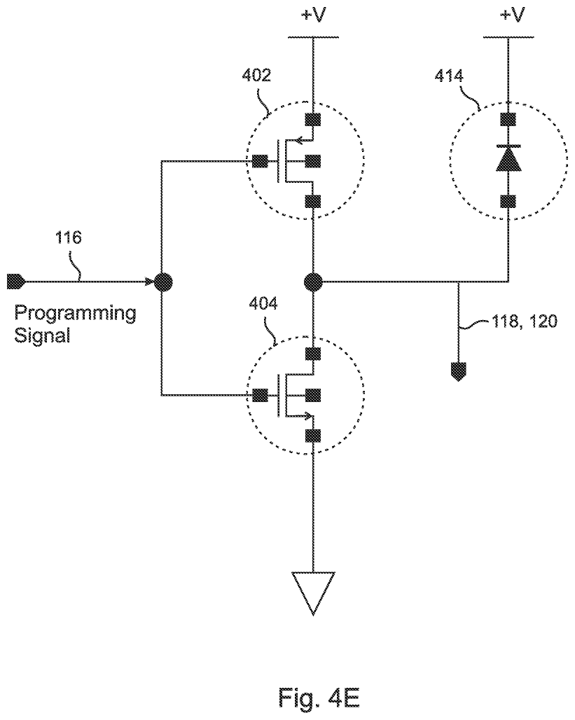

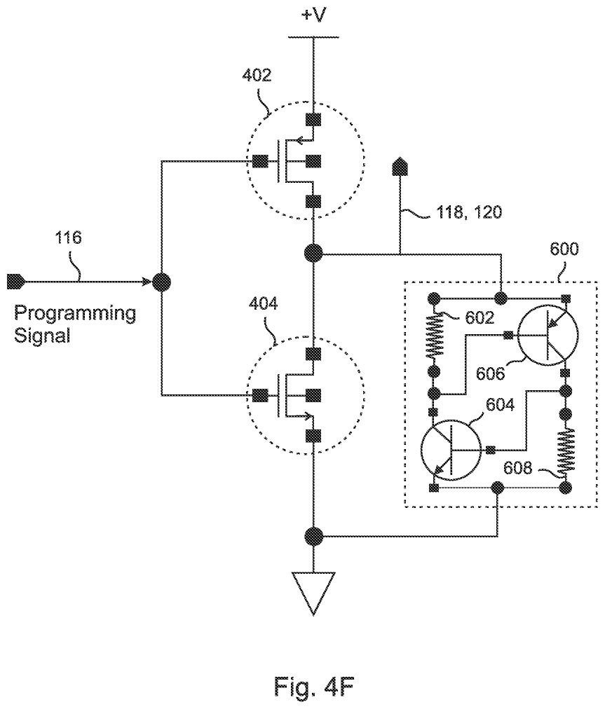

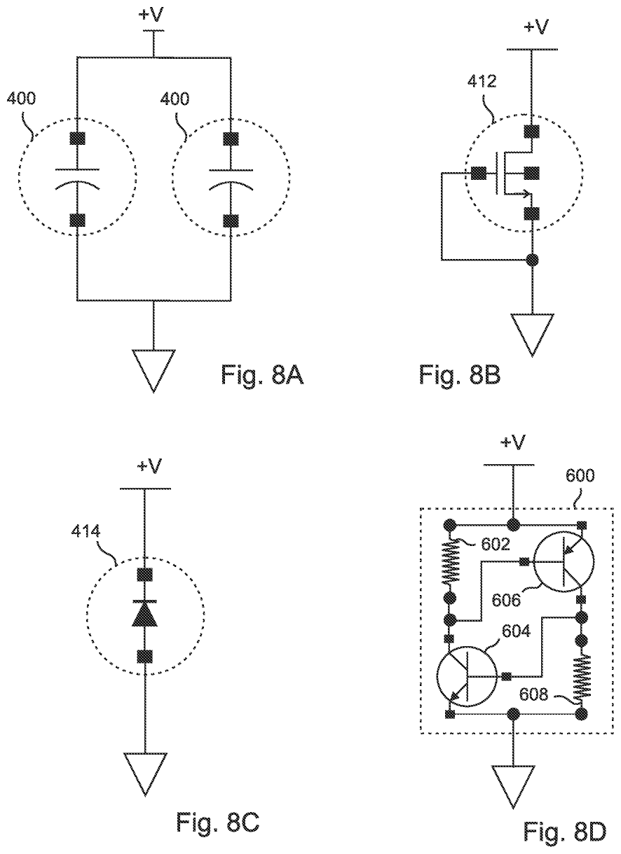

It should be noted that FIGS. 4A through 7 illustrate PRT ICs 100, while FIGS. 8A through 11 illustrate corresponding xRAD ICs 122 that include the RTLFs 104 but not the PRTs 106 of FIGS. 4A through 7.

With reference to FIGS. 4A-4B, according to a first example embodiment of a PRT IC 100, the RTLF 104 is a single event gate rupture (SEGR) degradation circuit that includes an oxide dielectric capacitor 400 as a “leakage” component that will be damaged and will develop a leakage current upon exposure to radiation above a certain linear energy transfer (LET) level. Similar embodiments include a MOSFET or another component or circuit as the “leakage component.” The susceptibility of the leakage component or circuit to damage by radiation is dependent on an amount of voltage applied across the leakage component or circuit. In the example of FIG. 4A, the oxide dielectric capacitor 400 extends from a voltage +V that is required for operation of the functionality section 102 of the PRT IC 100. The source of a p-channel MOSFET 402 also extends from +V. The drain of the p-channel MOSFET 402 is connected to the drain of an n-channel MOSFET 404 and also to the oxide dielectric capacitor 400, while the source of the n-channel MOSFET 404 is connected to ground. The programming input 116 is connected to the gate inputs of both the p-channel MOSFET 402 and the n-channel MOSFET 404.

In similar embodiments, a separate leakage voltage that is not otherwise required for operation of the functionality section 102 of the PRT IC 100 is applied across the leakage component 400, which in some embodiments can be adjusted so as to adjust the radiation sensitivity of the RTLF 104.

In the example of FIG. 4A, the programming input 116 of the PRT IC 100 at the time of manufacture is set to logic 1, which causes the p-channel MOSFET 402 to be “off” (non-conducting) while the n-channel MOSFET 404 is “on.” Accordingly, +V is applied across the oxide dielectric capacitor 400, causing it to be sensitive to radiation exposure. When exposed to radiation, the oxide dielectric capacitor 400 will develop leakage, which will cause current to flow from +V through the oxide dielectric capacitor 400 and through the n-channel MOSFET 404 to ground. When this leakage current reaches a certain level, +V will essentially be shorted to ground, and the PRT IC 100 will be disabled.

However, subsequent to the manufacturing of the PRT IC 100, if the programming input 116 is programmed to logic 0, then the p-channel MOSFET 402 will conduct, while the n-channel MOSFET 404 will not conduct. As a result, +V will not be applied across the oxide dielectric capacitor 400. This will cause the oxide dielectric capacitor 400 to be virtually unaffected by radiation exposure. Furthermore, even if the oxide dielectric capacitor 400 were to develop leakage due to radiation exposure, current would be unable to flow through the n-channel MOSFET 404, and for that reason no additional current load would be placed upon +V.

The ability of the programming input 116 to reliably deactivate the RTLF 104 can be verified by confirming that when the programming signal is set to logic 0, the test output 120 is at +V, indicating that no voltage is applied across the leakage component 400.

With reference to FIG. 4B, redundancy can be included in any of the PRT IC 100 and xRAD IC 122 examples presented herein. FIG. 4B illustrates an example of redundancy as applied to the RTLF/PRT circuit of FIG. 4A. In FIG. 4B, a second p-channel MOSFET 408 is added in parallel with the first p-channel MOSFET 402, and a second n-channel MOSFET 410 is added in series with the first n-channel MOSFET 404. The gates of the additional MOSFETs 408, 410 are connected to a second programming input 406. The two programming inputs 116, 406 are generally operated in tandem, i.e. both set to logic 1 upon initial manufacture, and both set to logic 0 when the PRT IC 100 is reprogrammed to be radiation tolerant. However, if some failure should occur that would render it impossible to set one of the two programming inputs 116, 406 to logic 0, then setting the other programming input to logic 0 would nevertheless program the PRT IC 100 to be radiation tolerant.

Similarly, embodiments include redundant RTLFs 104 configured so that triggering of any one of them will disable the functional section 102, so long as none of the PRTs 106 has been actuated.

With reference to FIG. 4C, according to a method embodiment of the present disclosure, the functionality of the PRT 106 of FIG. 4B can be verified by the following sequence of steps. First, programming signal A 116 is set to logic 0 and programming signal B 406 is set to logic 1 416. The test signal 120 is then monitored 418 to ensure that there is little or no voltage applied across capacitor 400. Programming signal A 116 is then set to logic 1 and programming signal B 406 is set to logic 0 420. Again, test signal 120 is monitored 422 to ensure that there is little or no voltage applied across capacitor 400. Programming signal A 116 is reset to logic 1 424, so that the PRT IC 100 is configured to be radiation intolerant. Finally, test signal 120 is monitored 426 to ensure that voltage +V is applied across capacitor 400. In this manner, the correct operation of both programming signals 116, 406 are separately tested, thereby confirming that the PRT redundancy provides protection against a failure that would cause a PRT IC 100 that is intended to be radiation tolerant to become radiation intolerant during operation. The approach of FIG. 4C is easily extended to PRT ICs 100 that include more than two redundant PRTs 106.

With reference to FIG. 4D, in embodiments similar to FIG. 4A the oxide dielectric capacitor 400 is replaced by a radiation sensitive MOSFET 412, thereby providing an RTLF 104 that is susceptible to total ionizing dose radiation effects when the programming signal 116 is set to Logic 0, while the PRT IC 100 is rendered radiation tolerant when the programming signal 116 is set to Logic 1. Note that MOSFET 412 can be merged with MOSFET 404 to perform the same function. With reference to FIG. 4E, in other, similar embodiments the oxide dielectric capacitor 400 is replaced by a photocurrent generating component 414, which may be any device, such as a reverse biased diode 414 functional circuit, that produces a photocurrent in response to a dose rate event. As a result, the RTLF 104 is susceptible to dose rate radiation effects and provides event detection capabilities.

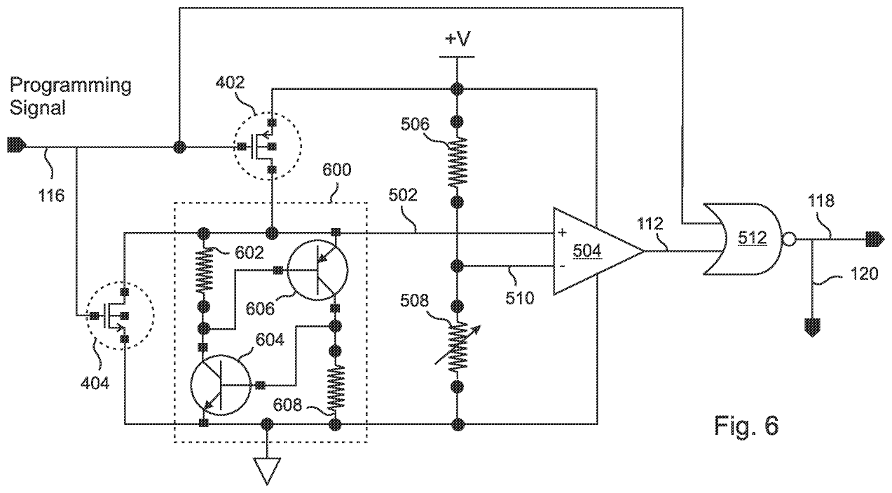

With reference to FIG. 4F, in yet other, similar embodiments the oxide dielectric capacitor 400 of FIG. 4A is replaced by a parasitic silicon-controlled rectifier (SCR) circuit 600 that latches up in response to charged particle hits above an LET value when the programming signal 116 is set to Logic 0, while the PRT IC 100 is rendered radiation tolerant when the programming voltage is set to Logic 1. Once latchup occurs, the SCR draws a high current as long as the voltage +V remains above the SCR sustaining voltage. The SCR radiation detection circuit 600 of FIG. 4F is described in more detail below in reference to FIG. 6.

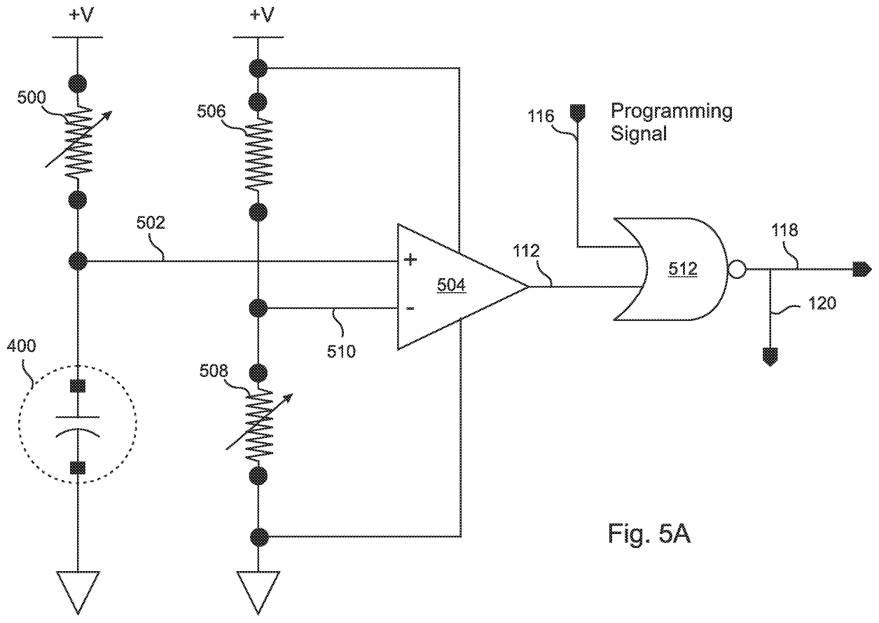

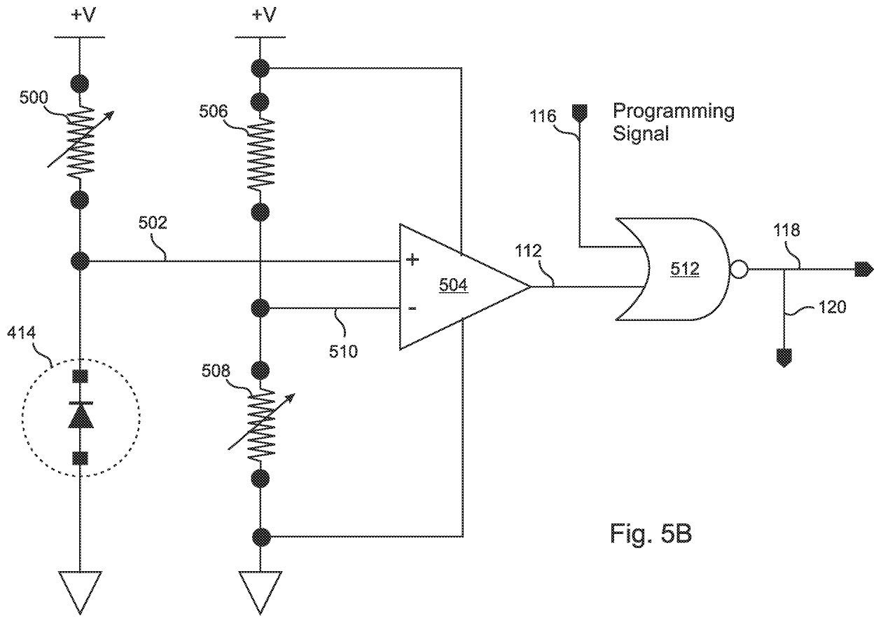

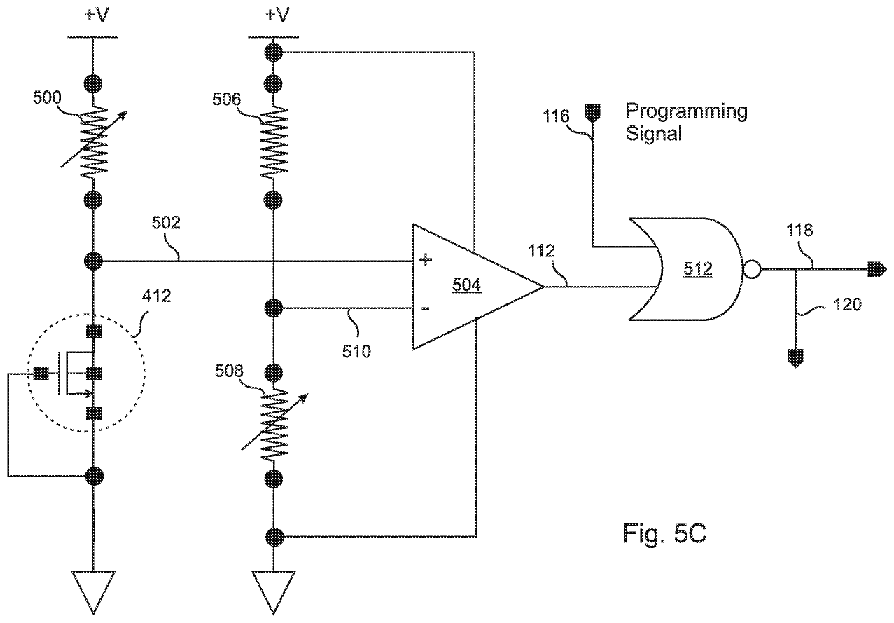

With reference to FIG. 5A, in which the RTLF 104 is a single event gate rupture (SEGR) degradation circuit, the RTLF 104 can be configured to disable the PRT IC 100 when a defined amount of leakage through a leakage component due to radiation exposure is reached. In FIG. 5A, the leakage component 400 is an oxide dielectric capacitor 400, which is combined in series with a first variable resistor 500 to form a voltage divider that extends from +V to ground. The voltage divider directs a leakage voltage 502 to the positive input of a differential amplifier 504. A second voltage divider formed by a fixed resistor 506 in series with a second variable resistor 508 also extends between +V and ground, and directs a reference voltage 510 to the negative input of the differential amplifier 504. The differential amplifier 504 compares the leakage and reference voltages, and transitions its output, which functions as a disabling signal 112, from logic 1 to logic 0 if the leakage voltage drops below the reference voltage.

The PRT 106 in this example comprises a NOR gate 512 that receives the disabling signal 112 together with a programming signal 116. The output of the NOR gate 512 is directed as a control signal 118 to a reset input 110 of the functional section 102. Upon initial manufacture, the programming signal 116 is set to logic 0, such that the reset output 118 follows the inverse of the disabling signal 112. Before exposure to radiation, the disabling signal 112 is logic 1, causing the control signal to be logic 0, thereby allowing the functionality section 102 to operate normally. When the PRT IC 100 is exposed to sufficient radiation to cause the leakage voltage 502 to drop below the reference voltage 510, then the disabling signal 112 transitions to logic 0 and the control signal 118 transitions to logic 1, thereby deactivating the functionality section 102.

However, if the programming signal 116 is programmed to logic 1 after the initial manufacture of the PRT IC 100, then the control output of the NOR gate 118 will be held at logic 0, thereby allowing the functionality section 102 to operate normally, regardless of the status of the leakage component 400 and disabling signal 112.

The variable resistors 500, 508 in the example of FIG. 5A can be adjusted to control the amount of leakage current that must be reached before the disable signal 112 transitions from logic 1 to logic 0. In similar embodiments, these components 500, 508 are replaced by fixed value components. For example, test ICs can be produced with variable resistors 500, 508, which can be used during testing to determine optimal resistance values. Subsequently, the variable resistors 500, 508 can be replaced by fixed resistors having the determined resistance values.

Redundancy can be added to the example of FIG. 5A in a manner similar to FIG. 4B. For example, two NOR gates can be provided in parallel, where the disabling signal 112 is directed to both of the NOR gates, while separate programming signals 116 are directed to the two NOR gates.

With reference to FIG. 5B, in similar embodiments the oxide dielectric capacitor 400 is replaced by a photocurrent generating component 414, which may be any device, such as a reverse biased diode 414 functional circuit, that produces a photocurrent in response to a dose rate event. As a result, the RTLF 104 is susceptible to dose rate radiation effects and provides event detection capabilities.

With reference to FIG. 5C, in similar embodiments the oxide dielectric capacitor 400 is replaced by an n-channel MOSFET that is sensitive to total ionizing dose.

The example embodiment of FIG. 6, in which the RTLF 104 comprises a single event latch-up (SEL) degradation circuit 600, combines features of the embodiments of FIGS. 4F and 5A. In FIG. 6, a leakage circuit 600 comprising four components 602, 604, 606, 608 functions as a single event latch-up (SEL) degradation circuit 600 that supplies a leakage voltage 502 to the positive input of a voltage comparator 504. Also, the programming signal 116 in FIG. 6 functions in a manner similar to FIG. 4F by driving the gates of a p-channel MOSFET 402 and an n-channel MOSFET 404 arranged in series. The programming signal is also directed to a NOR gate 512 that functions in a similar manner to the example of FIG. 5A. The negative input of the voltage comparator 504 is driven by a reference voltage 510 derived from a voltage divider formed by a pair of resistors 506, 508, in a manner similar to FIG. 5A. The leakage circuit 600 functions as a parasitic silicon-controlled rectifier (SCR). The parasitic SCR 600 is naturally occurring in bulk CMOS semiconductor processes and its contribution to electrically induced latch-up is well documented. In embodiments, the parasitic SCR 600 is designed to be susceptible to charged particle induced latch-up by optimizing the parasitic n-well 602 and p-well 608 resistances as well as the physical distance between the p+ and n+ junction regions.

The programming signal 116 is initially set to logic 0, causing the n-channel MOSFET 404 to be “off” (non-conducting) while the p-channel MOSFET 402 is “on” (conducting), thus biasing the parasitic SCR 600 to near +V. In this bias condition, the parasitic SCR 600 is trigged during radiation exposure by a charged particle physically traversing through its sensitive region, resulting in a single event latch-up (SEL) condition. This causes the leakage voltage 502 to drop below the reference voltage 510, so that the disabling signal output 112 of the voltage comparator 504 transitions to logic 0, which in turn causes the control signal 118 to transition to logic 1. The net result is that the functional section 102 of the PRT IC 100 is disabled.

When the programming signal 116 is set to logic 1, this causes the n-channel MOSFET 404 to be “on” (conducting) and the p-channel MOSFET 402 to be “off” (non-conducting), thereby biasing the parasitic SCR 600 to near ground. In this bias condition, the parasitic SCR 600 is incapable of being triggered by a charged particle physically traversing through its sensitive area, because the SCR circuit 600 is inoperative when no voltage is applied to it. Furthermore, the control signal 118 of the NOR gate 512 is forced remain in logic 0 state regardless of the status of the parasitic SCR 600 and the disabling signal 112.

In any of the embodiments of FIGS. 4A-6, the voltage V+ applied to circuit elements 400, 412, 414 and 600 may be increased above the nominal supply voltage using, for example, an on-die charge pump, to increase susceptibility to radiation.

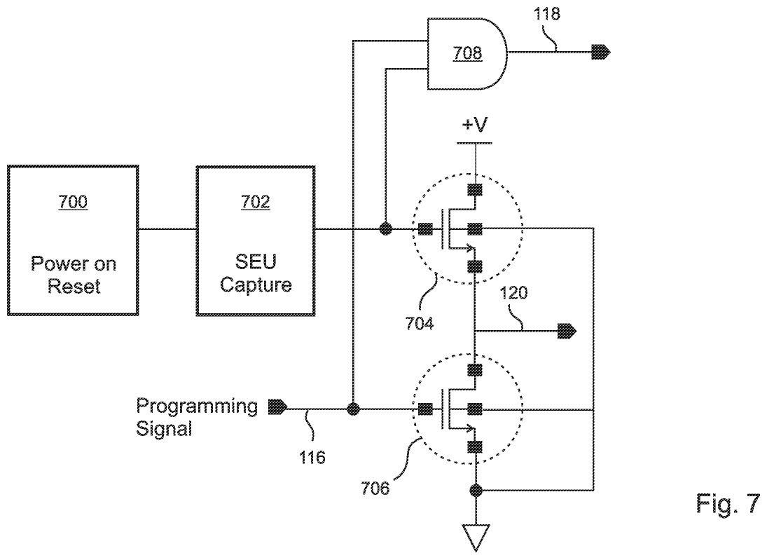

In the example embodiment of FIG. 7, the RTLF 104 is a single event upset (SEU) capture circuit 702 having an output that is initially set to logic 0 by the power on reset circuit 700 when power is initially applied to the PRT IC 100. In embodiments, the SEU capture circuit 702 includes a plurality of SEU capture components having outputs that are directed to an OR gate (not shown), so that the output of the RTLF 702 will only be logic 0 if all of the SEU capture components are logic 0. In various embodiments, single event upsets can be caused by exposure to heavy ions, protons, or neutrons. The programming signal 116 is initially set to logic 1, causing the n-channel MOSFET 706 to conduct. As a result, the reset output 118 generated by the AND gate 708 is initially logic 0. In addition, n-channel MOSFET 704 does not conduct, thereby preventing +V from being connected to ground.

If any one or more of the SEU components undergoes a SEU event, then the output of the SEU capture circuit 702 transitions to logic 1, causing the reset output 118 to transition to logic 1. At the same time, n-channel MOSFET 704 is caused to conduct, thereby connecting +V to ground, thereby further disabling the functionality section 102. The embodiment of FIG. 7 thereby provides two separate mechanisms that both disable the functional section 102 when the PRT IC as initially manufactured is exposed to radiation.

When the programming signal 116 is set to logic 0, then the reset output 118 is forced to logic 0 regardless of the status of the SEU capture circuit 702. At the same time, MOSFET 706 is blocked from conducting, thereby ensuring that +V is not connected to ground.

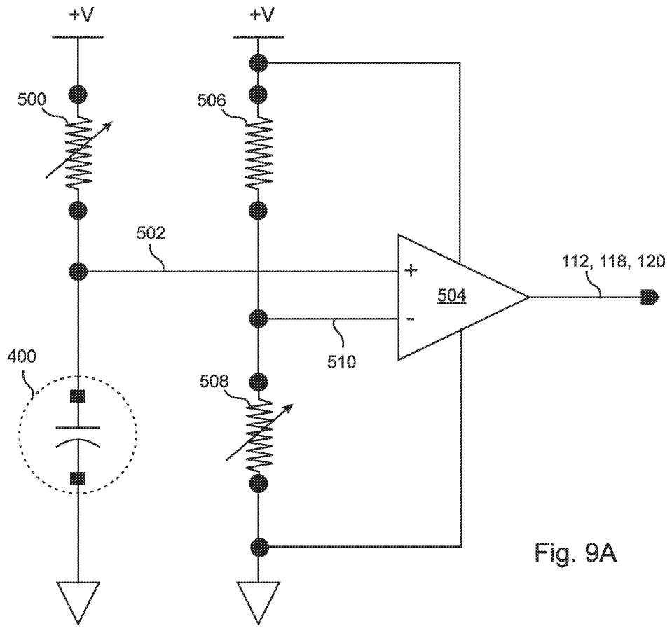

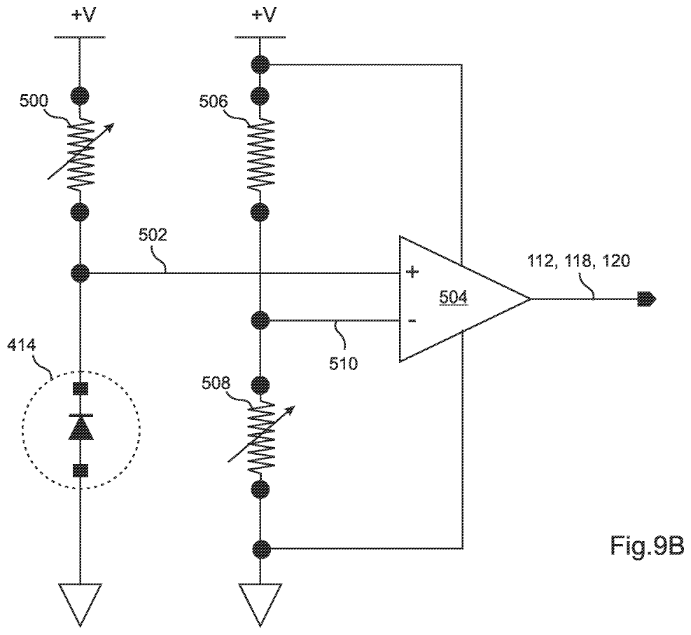

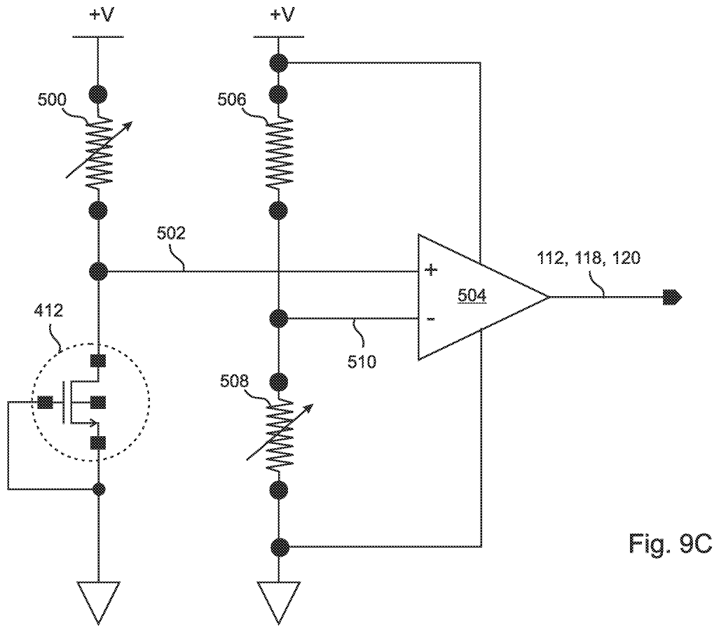

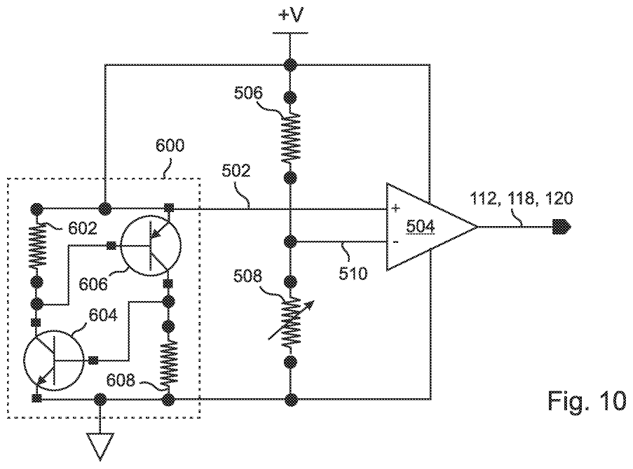

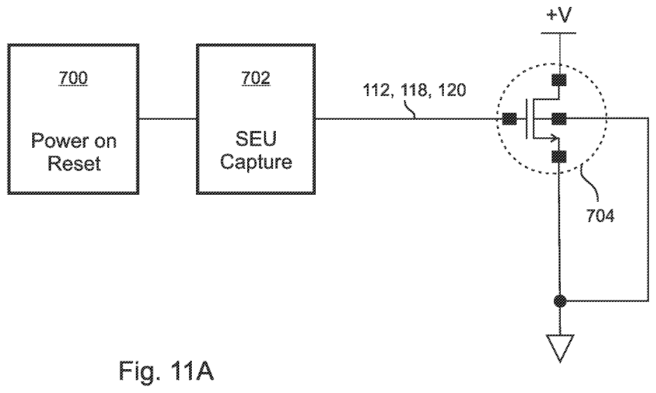

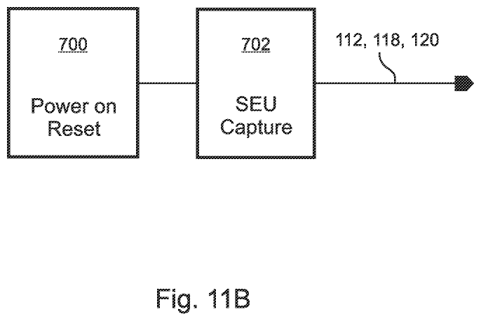

As noted above, FIGS. 8A-11 illustrate xRAD ICs 122 that include the RTLFs 104 of the PRT ICs 100 of FIGS. 4A-7, but do not include the PRT features 106 of FIGS. 4A-7. In particular, FIG. 8A corresponds to FIG. 4B, in that it includes redundancy to ensure that the RTLF 104 will render the xRAD IC 122 radiation intolerant. Similarly, FIGS. 8B-8D correspond to FIGS. 4D-4F respectively, FIGS. 9A and 9B corresponds to FIGS. 5A and 5B, respectively, FIG. 10 corresponds with FIG. 6, and FIG. 11A corresponds with FIG. 7. FIG. 11B illustrates a circuit that is similar to FIG. 11A, but does not include the MOSFET 704. Instead, the SEU directly issues a disabling signal 118.

While redundancy is only illustrated in FIG. 8A, it will be understood that the RTLF 104 and/or PRT 106 of any of the illustrated xRAD IC examples 122 or PRT IC examples 100 can include redundancy to ensure that the IC as manufactured will be radiation intolerant, and will reliably be reprogrammed to be radiation tolerant when the PRT 106 is actuated.

It should further be noted that the RTLF 104 examples presented in FIGS. 8A-11 can be included in an xRAD IC 122 in any desired combination, so as to ensure that the xRAD IC 122 will fail any desired combination of applicable radiation tolerance tests, including total radiation dosage, events over a Linear Energy Transfer (LET) level (e.g. via gate rupture), radiation dose rate, total dose and single event upset (SEU). In particular, it should be clear that the RTLF 104 embodiments of the present disclosure are not limited to only ensuring that the PRT IC or xRAD IC 122 will fail a total radiation dosage tolerance test.

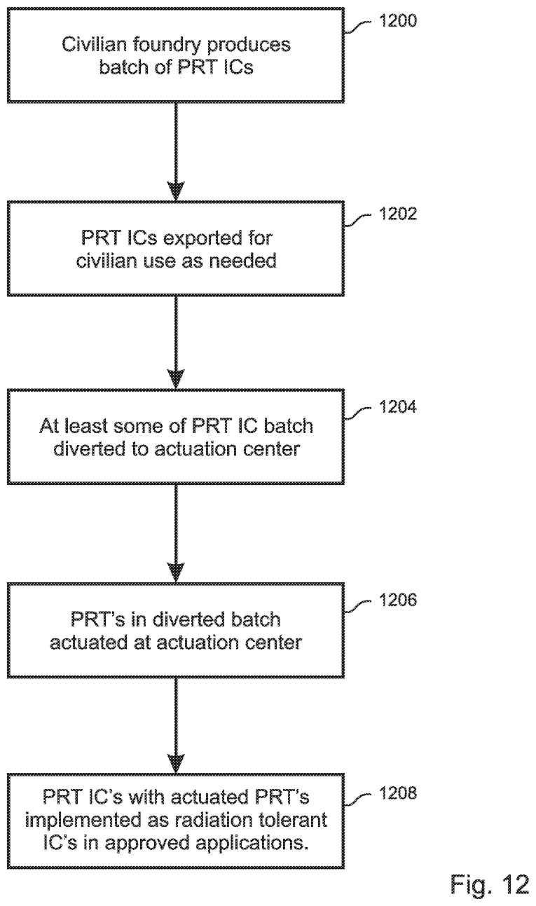

With reference to FIG. 12, in a method embodiment of the present disclosure a batch of PRT IC's 100 is produced 1200 by an IC foundry that is not licensed or certified to produce radiation tolerant IC's. The PRT ICs, as manufactured, are radiation intolerant, and are ensured to fail one or more radiation tolerance tests as determined by the RTLF features 104 that are included in the PRT ICs 100. As such, the PRT ICs 100, as manufactured, can be produced by foundries that are not radiation certified, and can be distributed and exported 1202 as needed without being subject to radiation tolerance export restrictions.

However, some or all of the batch of PRT ICs 100 are diverted to a secure actuation center 1204 that is licensed and certified to produce radiation tolerant ICs. At the secure actuation center, the PRT features 106 of the PRT ICs 100 are actuated 1206, thereby nullifying the RTLF features 104 of the PRT ICs 100, and converting the PRT ICs 100 into radiation tolerant ICs that can be implemented 1208 in military and other approved applications (e.g. civilian satellite applications) as needed.

The foregoing description of the embodiments of the disclosure has been presented for the purposes of illustration and description. Each and every page of this submission, and all contents thereon, however characterized, identified, or numbered, is considered a substantive part of this application for all purposes, irrespective of form or placement within the application. This specification is not intended to be exhaustive or to limit the disclosure to the precise form disclosed. Many modifications and variations are possible in light of this disclosure.

Although the present application is shown in a limited number of forms, the scope of the disclosure is not limited to just these forms, but is amenable to various changes and modifications. The disclosure presented herein does not explicitly disclose all possible combinations of features that fall within the scope of the disclosure. The features disclosed herein for the various embodiments can generally be interchanged and combined into any combinations that are not self-contradictory without departing from the scope of the disclosure. In particular, the limitations presented in dependent claims below can be combined with their corresponding independent claims in any number and in any order without departing from the scope of this disclosure, unless the dependent claims are logically incompatible with each other.

1. An integrated circuit (IC) having programmable radiation tolerance, the IC comprising:
a functionality section that is configured to withstand exposure to radiation up to a specified functional threshold, thereby ensuring that the functionality section is suitable for implementation in a high radiation environment;
a radiation tolerance limiting feature (RTLF) that is configured, when it is triggered, to partially or fully disable operation of the functionality section, the RTLF being triggered when it is exposed to radiation above a specified RTLF trigger threshold, the RTLF trigger threshold being low enough to ensure that the IC will fail at least one applicable radiation tolerance test as specified by an applicable regulatory requirement;
a programming input; and
a programmable radiation tolerance (PRT) feature that can be actuated after initial manufacture of the IC via the programming input so as to override the RTLF and thereby maintain operation of the functionality section despite triggering of the RTLF, thereby rendering the IC suitable for implementation in the high radiation environment.

2. The IC of claim 1, wherein at least one of the RTLF and PRT is obfuscated within the IC design, thereby hindering recognition, and reverse engineering of the RTLF and/or PRT based on examination of lithography mask designs of the IC or analysis of the IC die.

3. The IC of claim 2, wherein at least one of the RTLF and PRT is configured to appear similar to another common IC circuit that does not function as a RTLF or PRT.

4. The IC of claim 2, wherein at least one of the RTLF and PRT is distributed among a plurality of physical locations within the IC.

5. The IC of claim 1, wherein the PRT can be actuated by uploading instructions via the programming input into a programmable element that is included within the PRT.

6. The IC of claim 5, wherein the programmable element is a field programmable gate array (FPGA).

7. The IC of claim 5, wherein the uploaded instructions are encrypted.

8. The IC of claim 1, wherein the PRT includes a password recognition feature that enables actuation of the PRT only when a specified password is entered via the programming input.

9. The IC of claim 8, further comprising a decoding function, wherein the decoding function of the IC includes cryptographic hashing, thereby preventing discovery of the password by reverse engineering of the IC.

10. The IC of claim 1, wherein the RTLF is configured to cause a required voltage of the IC to be reduced when the RTLF is triggered.

11. The IC of claim 1, wherein the RTLF is configured to issue a disabling signal that disables the functional section when the RTLF is triggered.

12. The IC of claim 1, wherein the RTLF includes a leakage component or circuit that is configured to develop a leakage when the leakage component or circuit is exposed to radiation while a voltage is applied to the leakage component or circuit.

13. The IC of claim 12, wherein the leakage component or circuit comprises at least one of:
an oxide dielectric capacitor;
a radiation-sensitive MOSFET;
a radiation-sensitive silicon-controlled rectifier (SCR); and
a photocurrent generating component or circuit.

14. The IC of claim 12, wherein the leakage component is implemented as part of a voltage divider that directs a leakage voltage to an input of a voltage comparator, and wherein the voltage comparator is configured to compare the leakage voltage with a reference voltage, and to cause the RTLF to be triggered when the leakage voltage transitions from being greater than the reference voltage to being less than the reference voltage, or vice versa.

15. The IC of claim 1, wherein the IC includes a plurality of RTLFs, thereby ensuring that the IC will fail a corresponding plurality of applicable radiation tolerance tests.

16. The IC of claim 1, wherein the PRT is configured, when actuated, to prevent a disabling signal issued by the RTLF from acting upon the functional section.

17. The IC of claim 1, wherein the PRT is configured, when actuated, to prevent application of a voltage to a leakage component or circuit of the RTLF.

18. The IC of claim 1, wherein the IC includes a redundancy feature comprising a plurality of RTLFs directed to ensuring that the IC will fail the applicable radiation tolerance test, and the IC will fail the specified radiation tolerance test, so long as any one of the RTLFs remains functional and the PRT has not been actuated.

19. The IC of claim 1, wherein the IC includes a redundancy feature comprising a plurality of PRTs, whereby the RTLF will remain overridden so long as any one of the PRTs remains functional and is actuated.

20. The IC of claim 1, wherein:
the applicable regulatory requirement is from at least one of the United States International Traffic in Arms Regulations (ITAR) and the United States Export Administration Regulations (EAR).

21. The IC of claim 1, wherein the RTLF trigger threshold is adjustable by changing a value of at least one adjustment component of the RTLF.

22. The IC of claim 1, wherein the RTLF trigger threshold is adjustable by changing a value of a voltage applied across a radiation sensitive component of the RTLF.

23. The IC of claim 1, wherein the IC comprises a RTLF testing output that can be monitored without permanently triggering the RTLF to determine whether the RTLF is able to disable the functional section of the IC when it is triggered and the PRT is not actuated.

24. The IC of claim 1, wherein the IC comprises a PRT testing output that can be monitored without permanently actuating the PRT to determine whether the PRT is able to override the RTLF.

25. A method of manufacturing a radiation tolerant integrated circuit (IC), the method comprising:
manufacturing by an IC foundry that is not authorized to manufacture the IC that is capable of operating in a high radiation environment, wherein the IC comprises:
a functionality section that is configured to withstand exposure to radiation up to a specified functional threshold, thereby ensuring that the functionality section is suitable for implementation in the high radiation environment;
a radiation tolerance limiting feature (RTLF) that is configured, when it is triggered, to partially or fully disable operation of the functionality section and prevent operation in the high radiation environment, the RTLF being triggered when it is exposed to radiation above a specified RTLF trigger threshold, the RTLF trigger threshold being low enough to ensure that the IC will fail at least one applicable radiation tolerance test as specified by an applicable regulatory requirement;
a programming input; and
a programmable radiation tolerance (PRT) feature that can be actuated after initial manufacture of the IC via the programming input so as to override the RTLF and thereby maintain or restore operation of the functionality section despite triggering of the RTLF, thereby rendering the IC suitable for implementation in the high radiation environment.

26. (canceled)

27. (canceled)

28. The method of claim 25, further comprising actuating the PRT of the IC at an actuation center for operating in the high radiation environment.

29. The method of claim 25, wherein the actuation center is authorized to actuate the PRT.
